(19) United States
(12) Patent Application Publication
(10) Pub. No.: US 2013/0068277 A1
(43) Pub. Date: Mar. 21, 2013

(54) PHOTOVOLTAIC MODULE AND PHOTOVOLTAIC MODULE ARRAY

(71) Applicants: Kohtaroh KATAOKA, Osaka-shi (JP); Kohichiroh ADACHI, Osaka-shi (JP); Masatomi HARADA, Osaka-shi (JP); Yoshiji OHTA, Osaka-shi (JP); Hiroshi IWATA, Osaka-shi (JP); Shinpei HIGASHIDA, Osaka-shi (JP)

(72) Inventors: Kohtaroh KATAOKA, Osaka-shi (JP); Kohichiroh ADACHI, Osaka-shi (JP); Masatomi HARADA, Osaka-shi (JP); Yoshiji OHTA, Osaka-shi (JP); Hiroshi IWATA, Osaka-shi (JP); Shinpei HIGASHIDA, Osaka-shi (JP)

(73) Assignee: Sharp Kabushiki Kaisha, Osaka-shi (JP)

(21) Appl. No.: 13/588,562

(22) Filed: Aug. 17, 2012

(30) Foreign Application Priority Data
Sep. 21, 2011 (JP) 2011-206423

(51) Int. Cl. H01L 31/05

(52) U.S. Cl. 136/244

(57) ABSTRACT

A photovoltaic module of the present invention includes a cluster power generation unit in which multiple photovoltaic elements are connected in series via connection points, a pair of output terminals connected to respective ends of a series circuit formed by the cluster power generation unit, and a specified terminal connected to a specified connection point that is specified from among the connection points.

### CROSS-REFERENCE TO RELATED APPLICATION

This application claims priority under 35 U.S.C. §119(a) on Patent Application No. 2011-206423 filed in Japan on Sep. 21, 2011, the entire contents of which are herein incorporated by reference.

### BACKGROUND OF THE INVENTION

1. Field of the Invention

The present invention relates to a photovoltaic module that includes a cluster power generation unit in which multiple photovoltaic elements are connected in series via connection points, and to a photovoltaic module array configured by connecting multiple photovoltaic modules together.

2. Description of the Related Art

Solar cells have a low output voltage as individual elements, and therefore when they are applied, an appropriate solar cell module is prepared as necessary by configuring a solar cell cluster in which multiple solar cells are connected in series. In other words, a solar cell module is formed by connecting multiple solar cells in series, and there are cases where a variation in the amount of light irradiation for some solar cells (e.g., a shaded area) has an influence on the solar cell module as a whole.

For example, if only some of the solar cells connected in series become shaded, an imbalance in the irradiation area arises between the stages of the series. If the irradiation area differs between solar cells, the output of the series-connected solar cells will be limited by the solar cell having the lowest irradiation amount (solar irradiation amount). In other words, even if the shaded area is small, all of the series-connected solar cells are affected, and there are cases where the output is greatly limited.

Various techniques have been proposed as countermeasures for shaded areas (e.g., see JP H7-217087A, JP 2001-36125A, JP 2001-111083A, JP 2002-237612A, and JP 2010-287795A).

According to the technology disclosed in JP H7-217087A, the direction of cross-pieces for fixing a roof member incorporating solar cell elements and the direction of the series connection of the solar cell elements are set parallel to each other so as to equalize the reduction in the output of the solar cell elements due to shadows created by the cross-pieces. This is a countermeasure for a very specialized mode of avoiding the influence of shadows created by cross-pieces used in installation, not a general countermeasure for variation in the amount of light irradiation, and therefore cannot be said to be a so-called countermeasure for shaded areas. Furthermore, other applications of this technology would be very difficult.

According to the technology disclosed in JP 2001-36125A, solar cell modules configured by solar cell elements are arranged in a vertically stepped manner, and the direction of the series connection of the solar cell elements is set to a direction orthogonal to the vertical direction. Although this prevents a problem from arising even if an upper solar cell module creates a shadow on a lower solar cell module, this is a countermeasure directed to solar cell modules that are arranged in a vertically stepped manner, and is for avoiding the influence of shadows created by the solar cell modules. This is not a general countermeasure for variation in the amount of light irradiation, and therefore cannot be said to be a so-called countermeasure for shaded areas. Furthermore, other applications of this technology would be very difficult.

According to the technology disclosed in JP 2001-111083A, the lengthwise direction of solar cells and the lengthwise direction of solar cell modules formed by arranging the solar cells are set so as to be orthogonal to each other so as to diminish a reduction in output due to a shadow created by a step portion when the solar cell modules are stacked in steps. This is not a general countermeasure for variation in the amount of light irradiation, and therefore cannot be said to be a so-called countermeasure for shaded areas. Furthermore, other applications of this technology would be very difficult.

According to the technology disclosed in JP 2002-237612A, the number of solar cell modules that are installed is set high in advance for solar cell arrays that are installed in places where shadows are created. This is not a general countermeasure for variation in the amount of light irradiation, and therefore cannot be said to be a so-called countermeasure for shaded areas. Furthermore, other applications of this technology would be very difficult.

According to the technology disclosed in JP 2010-287795A, solar cells that configure solar cell modules and arranged in parallel lines so as to form a matrix. This technology is limited to a countermeasure in a matrix configured by photovoltaic modules.

As described above, conventional solar cell modules have been limited to the application of countermeasures for predetermined shadows. In other words, random variation in the amount of light irradiation has not been taken into consideration at all. Although it is conceivable to use bypass diodes as a countermeasure for random variation in the amount of light irradiation, it is difficult to avoid power loss and a reduction in output due to the bypass diodes.

### SUMMARY OF THE INVENTION

The present invention was achieved in light of such circumstances. Specifically, a photovoltaic module according to the present invention includes a specified terminal connected to a specified connection point that is specified from among the connection points of a cluster power generation unit in which multiple photovoltaic elements are connected in series via connection points, and thus multiple photovoltaic modules can be connected to each other in parallel.

Specifically, an object of the present invention is to provide a photovoltaic module according to which, in the case where multiple photovoltaic modules are connected to each other in parallel, the specified terminals of the photovoltaic modules (cluster power generation units) are connected to each other so that the photovoltaic elements are connected to each other in parallel, and therefore if the photovoltaic power (current) decreases due to a shadow (shaded area or the like) on a photovoltaic element of one of the photovoltaic modules (cluster power generation units), for example, the generated current flows via the parallel circuit of another photovoltaic module (cluster power generation unit) that is connected in parallel to the one photovoltaic module, thus making it possible to suppress the influence of the reduction in generated current (output) due to the shadow and prevent a shadow from influencing the photovoltaic modules.

Also, another object of the present invention is to provide a photovoltaic module array in which multiple photovoltaic modules of the present invention are linked to each other so as to make it possible to easily and reliably suppress the influence of a shadow on a photovoltaic element and improve the power generation efficiency, and stably generate a large amount of electricity from light.

A photovoltaic module according to one aspect of the present invention includes: a cluster power generation unit in which a plurality of photovoltaic elements are connected in series via connection points; a pair of output terminals connected to respective ends of a series circuit formed by the cluster power generation unit; and a specified terminal connected to a specified connection point that is specified from among the connection points.

In the case where multiple photovoltaic modules are connected to each other in parallel, and the photovoltaic power (current) decreases due to a shadow (shaded area or the like) on a photovoltaic element of one of the photovoltaic modules (cluster power generation units), for example, the current (output) is suppressed in the series circuit of the one photovoltaic module according to conventional technology. However, according to the above-described photovoltaic module of the present invention, the specified terminals of the photovoltaic modules (cluster power generation units) are connected to each other such that the photovoltaic elements are connected to each other in parallel, and therefore the generated current flows via the parallel circuit of another photovoltaic module (cluster power generation unit) that is connected in parallel to the one photovoltaic module, thus making it possible to suppress the influence of the reduction in generated current (output) due to the shadow and prevent a shadow from influencing the photovoltaic modules.

Also, with the above-described photovoltaic module of the present invention, the specified connection point may be a connection point at a boundary between sections obtained by sectioning the photovoltaic elements of the cluster power generation unit into sections of the same series number.

According to the above-described photovoltaic module of the present invention, the photovoltaic elements are arranged using a uniform parallel condition for being sectioned into sections of the same series number such that the number of specified connection points is less than the number of connection points, thus making it possible to simplify the connection topology, improve the degree of freedom of connection, and achieve an effective connection topology.

Also, with the above-described photovoltaic module of the present invention, letting Voc be an open voltage and Vp be a peak inverse voltage of the photovoltaic elements, and letting the series number be k (k≧2), the relationship Vp>(k−1)×Voc may be satisfied.

According to the above-described photovoltaic module of the present invention, the specified connection point is connected to the specified connection point corresponding to the same series stage in another photovoltaic module, and the photovoltaic elements are configured so as to satisfy the relationship Vp>(k−1)×Voc, thus enabling preventing the hotspot phenomenon without the connection of a bypass diode, which enables reducing the number of parts so as to improve productivity and reliability.

Also, with the above-described photovoltaic module of the present invention, all of the connection points may be specified connection points.

According to the above-described photovoltaic module of the present invention, all of the series-connected photovoltaic elements of the cluster power generation unit can be connected in parallel to another photovoltaic module, thus enabling highly suppressing the influence of a shadow and suppressing a reduction in power generation efficiency.

Also, with the above-described photovoltaic module of the present invention, a plurality of the cluster power generation units may be arranged.

According to the above-described photovoltaic module of the present invention, it is possible to configure a distributed-arrangement photovoltaic module in which photovoltaic elements that are connected in the same series stage of the cluster power generation units are arranged so as to be distributed according to the number of cluster power generation units, thus making it possible to reliably diminish the influence of a shadow.

Also, with the above-described photovoltaic module of the present invention, an arrangement of the photovoltaic elements in one of the cluster power generation units and an arrangement of the photovoltaic elements in another one of the cluster power generation units may be mutually different with respect to the same series stage.

According to the above-described photovoltaic module of the present invention, the arrangement of the photovoltaic elements (the positions where they appear on the surface of the cluster power generation unit) is set so as to be different between multiple cluster power generation units, thus making it possible to improve the degree of distribution in the arrangement of photovoltaic elements that are connected in parallel in the same series stage, thus enabling further raising the effect of the distributed arrangement.

Also, with the above-described photovoltaic module of the present invention, the output terminals and/or the specified terminal may be arranged along one side formed by the cluster power generation unit, or may be arranged so as to be aggregated together in a corner portion formed by the cluster power generation unit.

According to the above-described photovoltaic module of the present invention, a photovoltaic module can be easily connected to another photovoltaic module that is arranged adjacent thereto, thus making it easier to increase the capacity through a dense arrangement.

Also, with the above-described photovoltaic module of the present invention, the output terminals and/or the specified terminal may be respectively branched and arranged along two sides formed by the cluster power generation unit on opposite sides, or may be arranged so as to be aggregated together in two or more corner portions formed by the cluster power generation unit.

According to the above-described photovoltaic module of the present invention, photovoltaic modules can easily be two-dimensionally connected to other photovoltaic modules that are arranged adjacent thereto, thus making it even easier to increase the capacity through a dense arrangement.

Also, the above-described photovoltaic module of the present invention may include a wiring portion arranged so as to extend in a parallel-arrangement direction of the plurality of cluster power generation units, wherein the output terminals and the specified terminal may be arranged in the wiring portion.

According to the above-described photovoltaic module of the present invention, a dense arrangement can be achieved using the wiring portion, thus making it easy to increase the capacity.

Also, with the above-described photovoltaic module of the present invention, the wiring portion may include output wiring that is connected to the output terminals and specified wiring that is connected to the specified terminal, the output wiring may be arranged in a central region with respect to an intersecting direction that intersects with the parallel-arrangement direction, and the specified wiring may be symmetrically arranged in side regions at two ends in the intersecting direction.

According to the above-described photovoltaic module of the present invention, when another photovoltaic module that is arranged adjacent to the above-described photovoltaic module is rotated 180 degrees, the two photovoltaic modules can be easily connected together without adding other wiring, and it is also easy to raise the degree of distribution of the photovoltaic elements in a dense arrangement.

Also, a photovoltaic module array according to another aspect of the present invention includes a plurality of photovoltaic modules and linking wiring that links the photovoltaic modules to each other, wherein the photovoltaic modules are each a photovoltaic module according to the present invention.

According to the above-described photovoltaic module array of the present invention, it is possible to easily and reliably suppress the influence of a shadow on a photovoltaic element so as to improve the power generation efficiency, and it is possible to stably generate a large amount of electricity from light.

A photovoltaic module according to the present invention includes a specified terminal connected to a specified connection point that is specified from among the connection points included in a cluster power generation unit in which multiple photovoltaic elements are connected in series.

In the case where multiple photovoltaic modules are connected to each other in parallel, and the photovoltaic power (current) decreases due to a shadow (shaded area or the like) on a photovoltaic element of one of the photovoltaic modules (cluster power generation units), for example, the current (output) is suppressed in the series circuit of the one photovoltaic module according to conventional technology. However, according to the above-described photovoltaic module of the present invention, the specified terminals of the photovoltaic modules (cluster power generation units) are connected to each other such that the photovoltaic elements are connected to each other in parallel, and therefore the generated current flows via the parallel circuit of another photovoltaic module (cluster power generation unit) that is connected in parallel to the one photovoltaic module, thus making it possible to suppress the influence of the reduction in generated current (output) due to the shadow and prevent a shadow from influencing the photovoltaic modules.

Also, a photovoltaic module array according to the present invention includes multiple photovoltaic modules according to the present invention, and linking wiring that links the photovoltaic modules to each other.

The above-described photovoltaic module array of the present invention has an effect of making it possible to easily and reliably suppress the influence of a shadow on a photovoltaic element so as to improve the power generation efficiency, and making it possible to stably generate a large amount of electricity from light.

### BRIEF DESCRIPTION OF THE DRAWINGS

FIG. 1 is a conceptual diagram that conceptually shows photovoltaic elements in a photovoltaic module and the arrangement and connections of a cluster power generation unit according to a first embodiment of the present invention.

FIG. 2 is a conceptual diagram that conceptually shows photovoltaic elements in a photovoltaic module and the arrangement and connections of a cluster power generation unit according to a second embodiment of the present invention.

FIG. 3 is a conceptual diagram that conceptually shows photovoltaic elements in a photovoltaic module and the arrangement and connections of a cluster power generation unit according to a third embodiment of the present invention.

FIG. 4 is a conceptual diagram that conceptually shows photovoltaic elements in a photovoltaic module and the arrangement and connections of cluster power generation units according to a fourth embodiment of the present invention.

FIG. 5A is a conceptual diagram that conceptually shows photovoltaic elements in a photovoltaic module and the arrangement and connections of cluster power generation units according to a fifth embodiment of the present invention.

FIG. 5B is a conceptual diagram that conceptually shows a variation of the arrangement of specified terminals of wiring in the photovoltaic module shown in FIG. 5A.

FIG. 6 is a conceptual diagram that conceptually shows the arrangement and connections of photovoltaic modules in a photovoltaic module array according to a sixth embodiment of the present invention.

FIG. 7 is a conceptual diagram that conceptually shows the arrangement and connections of photovoltaic modules in a photovoltaic module array according to a seventh embodiment of the present invention.

### DESCRIPTION OF THE PREFERRED EMBODIMENTS

First to seventh embodiments of the present invention are described below with reference to the drawings.

### First Embodiment

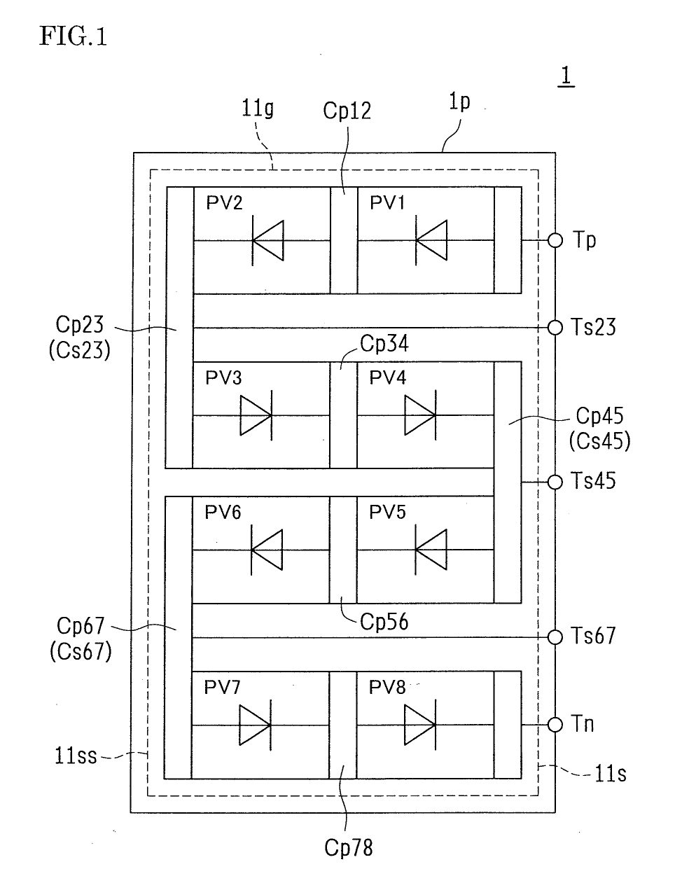

The following describes a photovoltaic module 1 according to a first embodiment with reference to FIG. 1.

FIG. 1 is a conceptual diagram that conceptually shows photovoltaic elements PV1 to PV8 in the photovoltaic module 1 and the arrangement and connections of a cluster power generation unit 11g according to the first embodiment of the present invention.

The photovoltaic module 1 of the present embodiment includes a cluster power generation unit 11g in which multiple photovoltaic elements PV (photovoltaic elements PV1 to PV8 in the present embodiment, which are hereinafter simply referred to as the photovoltaic elements PV when there is no particular need to distinguish between them) are connected in series via connection points Cp (connection points Cp12 to Cp78 at seven places, which are hereinafter simply referred to as the connection points Cp when there is no particular need to distinguish between them).

The photovoltaic module 1 also includes a pair of output terminals Tp and Tn that are respectively connected to the two ends of the series circuit (series of eight photovoltaic elements PV1 to PV8) configured by the cluster power generation unit 11g, and specified terminals Ts (specified terminals Ts23, Ts45, and Ts67, which are hereinafter simply referred, to as the specified terminals Ts when there is no particular need to distinguish between them (the same follows for other specified terminals Ts that are described later)) that are connected to specified connection points Cs (specified connection points Cs23, Cs45, and Cs67 at three places, which are hereinafter simply referred to as the specified connection points Cs when there is no particular need to distinguish between them (the same follows for other specified connection points Cs that are described later)) that have been specified from among the connection points Cp.

Accordingly, in the case where multiple photovoltaic modules 1 are connected to each other in parallel, if the photovoltaic power (current) decreases due to a shadow (shaded area or the like) on the photovoltaic elements PV of one of the photovoltaic modules 1 (cluster power generation unit 11g) for example, the overall current (output) of the series circuit (photovoltaic elements PV1 to PV8) of that one photovoltaic module 1 is suppressed when conventional technology is applied. However, since the specified terminals Ts of the photovoltaic modules 1 (cluster power generation units 11g) are connected to each other such that the photovoltaic elements PV are connected in parallel, the generated current flows via the parallel circuit of the another photovoltaic module 1 (cluster power generation unit 11g) that is connected in parallel to the one photovoltaic module 1, thus making it possible to suppress the influence of the reduction in generated current (output) due to the shadow and prevent the shadow from influencing the photovoltaic modules 1.

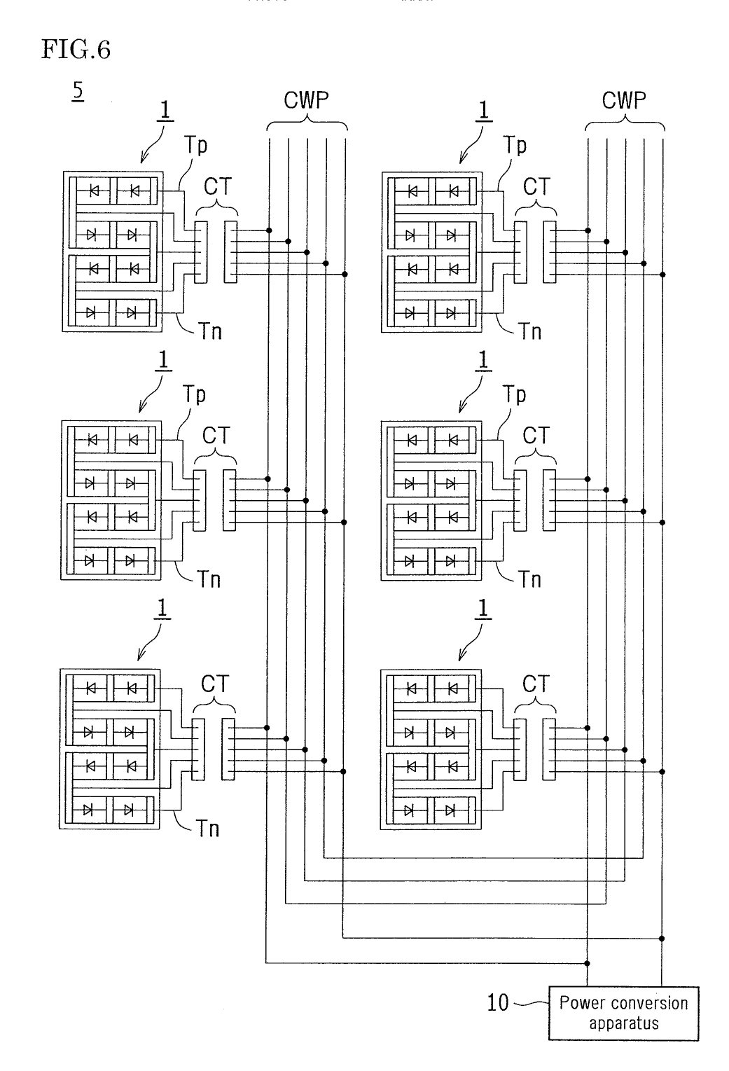

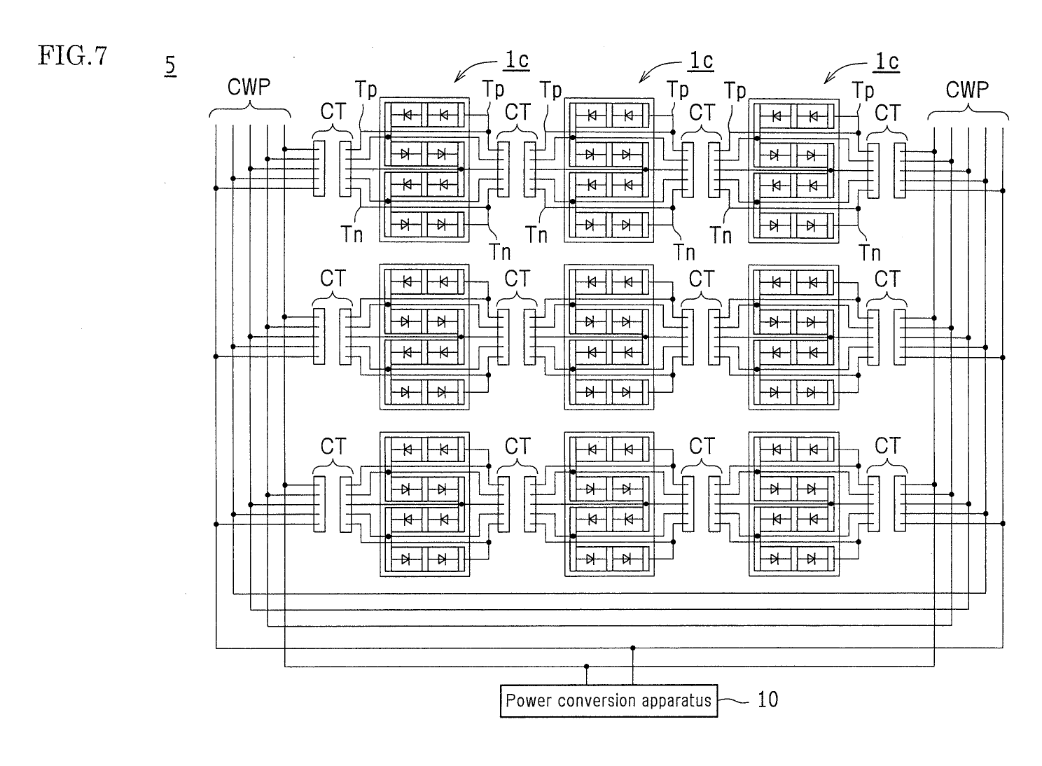

Although the cause of shadows is generally blockage of the sun, shadows are not limited to being caused by blockage of the sun, and there are cases where the photovoltaic elements PV are blocked from receiving light for some other reason during actual operation. The photovoltaic modules 1 are effective with respect to shadows that are larger than partial shadows that more or less influence one photovoltaic element PV, and thus are photovoltaic modules that are effective against partial shadows. Accordingly, a photovoltaic module array 5 (see FIGS. 6 and 7) that is effective against partial shadows can be configured, and a photovoltaic system (distributed-arrangement solar photovoltaic system) that is effective against partial shadows can be configured.

In the cluster power generation unit 11g, the photovoltaic elements PV are arranged in four rows and two columns. The photovoltaic element PV1 and the photovoltaic element PV2 are arranged in the first row from the top, the photovoltaic element PV3 and the photovoltaic element PV4 are arranged in the second row from the top, the photovoltaic element PV5 and the photovoltaic element PV6 are arranged in the third row from the top, and the photovoltaic element PV7 and the photovoltaic element PV8 are arranged in the fourth row from the top. Also, the photovoltaic element PV2, the photovoltaic element PV3, the photovoltaic element PV6, and the photovoltaic element PV7 are arranged in the first column from the left, and the photovoltaic element PV1, the photovoltaic element PV4, the photovoltaic element PV5, and the photovoltaic element PV8 are arranged in the second column from the left. Moreover, the photovoltaic elements PV are sectioned into sections of two each and arranged so as to form a new line in the opposite direction after each section.

In the photovoltaic module 1, the specified connection points Cs (specified connection point Cs23, specified connection point Cs45, and specified connection point Cs67) are the connection points Cp (connection point Cp23, connection point Cp45, and connection point Cp67) at the borders between the sections obtained by sectioning the photovoltaic elements PV (photovoltaic elements PV1 to PV8) of the cluster power generation unit 11g into sections of the same series number k (series number k=2 in the present embodiment).

Accordingly, with the photovoltaic module 1 of the present embodiment, the photovoltaic elements PV are arranged using a uniform parallel condition for being sectioned into sections of the same series number k such that the number of specified connection points Cs is less than the number of connection points Cp, thus making it possible to simplify the connection topology, improve the degree of freedom of connection, and achieve an effective connection topology.

It is also possible to set the series number of photovoltaic elements PV (e.g., photovoltaic element PV1 and photovoltaic element PV2) in each section (e.g., k=2) as necessary, thus making it possible to achieve an effective connection topology having an improved degree of freedom of connection.

The output terminal Tp, the output terminal Tn, and the specified terminals Ts are arranged along one side 11s formed by the cluster power generation unit 11g. Accordingly, the photovoltaic module 1 of the present embodiment can be easily connected to another photovoltaic module 1 that is arranged adjacent thereto, thus making it easier to increase the capacity through a dense arrangement (see FIG. 6).

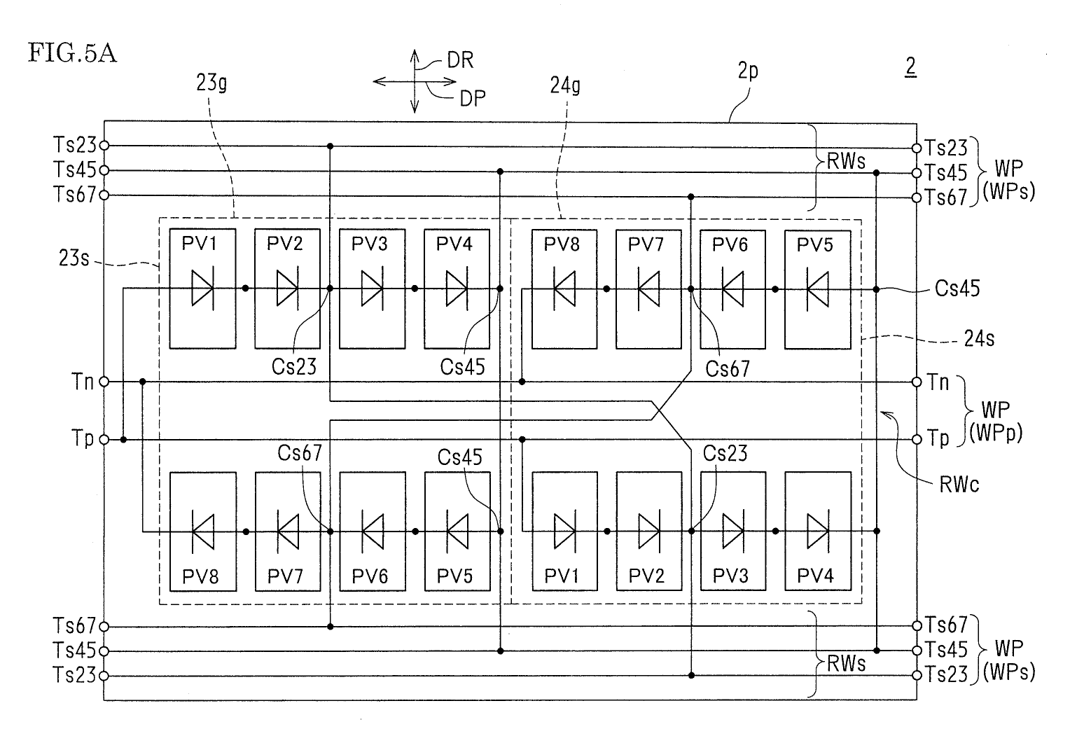

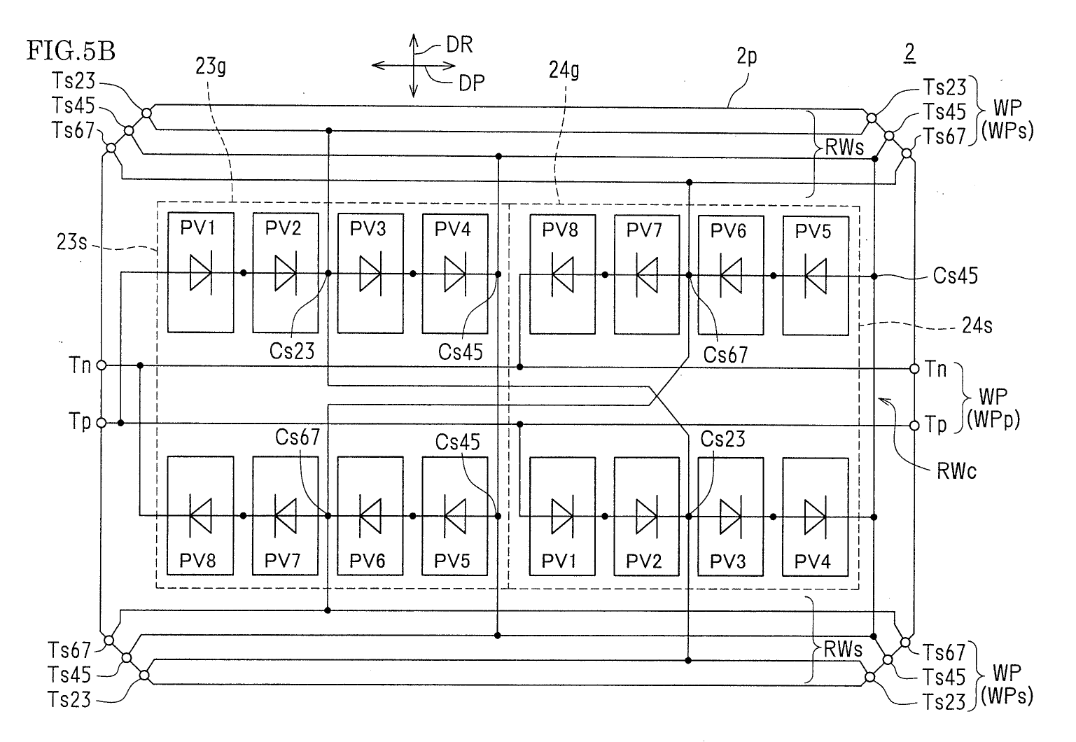

Also, the output terminal Tp, the output terminal Tn, and the specified terminals Ts may be arranged so as to be aggregated together at one of the corner portions formed by the cluster power generation unit 11g, and the photovoltaic module 1 of the present embodiment can be easily connected to another photovoltaic module 1 that is arranged adjacent thereto in this case as well. For example, a configuration is possible in which the output terminal Tp and the output terminal Tn are arranged along the one side 11s formed by the cluster power generation unit 11g, and the specified terminals Ts are arranged in one corner portion. Also, a configuration is possible in which, when necessary, any or all of the output terminal Tp, the output terminal Tn, and the specified terminals Ts are provided on the back face of the cluster power generation unit 11g. Note that FIG. 5B shows a specific arrangement example.

Besides the above-described case of the present embodiment, the following describes other examples of the relationship between the series number k, the number of sections, and the number of specified connection points Cs (specified terminals Ts) used when the series-connected photovoltaic elements PV that configure the series circuit (series stages) are sectioned into sections of the same series number.

In the case where the series circuit is configured by eight photovoltaic elements PV (photovoltaic elements PV1 to PV8) that are sectioned into two sections of four each (series number k=4), there is one specified terminal Ts. In the case where the series circuit (cluster power generation unit) is configured by nine photovoltaic elements PV that are sectioned into three sections of three each (series number k=3), there are two specified connection points Cs. In the case where the series circuit (cluster power generation unit) is configured by ten photovoltaic elements PV that are sectioned into five sections of two each (series number k=2), there are four specified connection points Cs, and in the case where the ten photovoltaic elements PV are sectioned into two groups of five each (series number k=5), there is one specified connection point Cs.

Note that in the present embodiment, the series circuit is configured by eight photovoltaic elements PV (photovoltaic elements PV1 to PV8) that are sectioned into four sections of two each (series number k=2) (so as to form the cluster power generation unit 11g), and thus there are three specified connection points Cs (specified connection point Cs23, specified connection point Cs45, and specified connection point Cs67).

As described above, the series number k, the number of sections, and the number of specified connection points Cs (number of specified terminals Ts) can be appropriately selected (set) according to the number of photovoltaic elements PV that are connected in series, and it is possible to optimally configure the combination of serial connections and parallel connections according to the overall specifications when multiple photovoltaic modules 1 are combined.

Also, when multiple photovoltaic modules 1 are linked by parallel connection, the photovoltaic elements PV that configure the photovoltaic modules 1 can be arranged so as to be distributed according to the number of parallel connections, thus making it possible to further distribute the influence of a shadow with respect to the same series stage and improve the substantial power generation efficiency.

The photovoltaic elements PV may take any form as long as they function (can be set) as individual power generation units. For example, in the case of a silicon crystal substrate, it is possible to use a cell that generates a unit of electromotive force with a pn junction. Also, the case of forming multiple pn junctions in series or parallel in a single substrate (monocrystal substrate, polycrystal substrate, or thin-film substrate) can also be handled in the same manner as the case of a single pn junction.

The connection point Cp12 is the connection position between the photovoltaic element PV1 and the photovoltaic element PV2, the connection point Cp23 is the connection position between the photovoltaic element PV2 and the photovoltaic element PV3, . . . , and the connection point Cp78 is the connection position between the photovoltaic element PV7 and the photovoltaic element PV8. Any connection topology may be used for the connection points Cp simply provided that photovoltaic elements PV are connected to each other.

The specified connection point Cs23 is the connection point Cp23, the specified connection point Cs45 is the connection point Cp45, and the specified connection point Cs67 is the connection point Cp67. In other words, the photovoltaic module 1 includes specified terminals Ts (specified terminal Ts23, specified terminal Ts45, and specified terminal Ts67) that are connected to specified connection points Cs (specified connection point Cs23, specified connection point Cs45, and specified connection point Cs67) that section the photovoltaic elements PV into sections of the same series number k (e.g., two photovoltaic elements each) (thus forming a series circuit including the photovoltaic element PV1 and the photovoltaic element PV2, a series circuit including the photovoltaic element PV3 and the photovoltaic element PV4, a series circuit including the photovoltaic element PV5 and the photovoltaic element PV6, and a series circuit including the photovoltaic element PV7 and the photovoltaic element PV8).

In the case where multiple photovoltaic modules 1 of the present embodiment are connected to each other in parallel, connecting the specified terminals Ts of the photovoltaic modules 1 to each other enables achieving a distributed arrangement of photovoltaic elements PV that are arranged in the same series stage of the cluster power generation units 11g (e.g., the photovoltaic element PV1 and the photovoltaic element PV2 of one photovoltaic module 1 are connected to the photovoltaic element PV1 and the photovoltaic element PV2 of another photovoltaic module 1), thus reliably suppressing the influence of a shadow and consequently realizing a high power generation efficiency.

The photovoltaic module 1 can be, for example, mounted on a mounting member 1p (wiring substrate or the like) so as to realize a single unit configuration. Note that although the wiring between the specified connection points Cs and the specified terminals Ts is shown as being aligned with the photovoltaic elements PV for the sake of convenience in the description, such wiring can be arranged on the back face side of the photovoltaic elements PV, for example. Also, the output terminal Tp, the output terminal Tn, and the specified terminals Ts may be connectors CT (see FIGS. 6 and 7), or may be patterned into a wiring substrate or the like.

The output terminal Tp, the output terminal Tn, and the specified terminals Ts do not need to be fixed to the mounting member 1p, and need only be capable of connecting to the outside (e.g., to another photovoltaic module 1 arranged adjacent thereto).

Note that a configuration is possible in which the output terminal Tp, the output terminal Tn, and the specified terminals Ts are respectively branched and arranged along two sides (the side 11s and a side 11ss) formed by the cluster power generation unit 11g on opposite sides (see FIG. 7). In this case, the photovoltaic module 1 can easily be two-dimensionally connected to other photovoltaic modules 1 (not shown) that are arranged adjacent thereto, thus making it even easier to increase the capacity through a dense arrangement (see FIG. 7).

Also, a configuration is possible in which the output terminal Tp, the output terminal Tn, or the specified terminals Ts are respectively branched and arranged so as to be aggregated together in two or more corner portions (preferably in all four corner portions) of the cluster power generation unit 11g, thus making it even easier to two-dimensionally connect the photovoltaic module 1 to other photovoltaic modules 1 (not shown) that are arranged adjacent thereto. Besides the row and column directions, this facilitates the expansion of connections in the diagonal directions.

For example, a configuration is possible in which the output terminal Tp and the output terminal Tn are respectively branched and arranged along two sides (the side 11s and the side hiss) formed by the cluster power generation unit 11g on opposite sides, and the specified terminals Ts are branched and arranged in multiple corner portions formed by the cluster power generation unit 11g.

Also, a configuration is possible in which, when necessary, any or all of the output terminal Tp, the output terminal Tn, and the specified terminals Ts are provided on the back face of the cluster power generation unit 11g.

Note that FIG. 5B shows a specific arrangement example.

Although the present embodiment describes the example where the cluster power generation unit 11g (series circuit in which multiple photovoltaic elements PV are connected in series) includes three specified connection points Cs (specified terminals Ts), a greater effect than in the case of a simple series circuit is obtained as long as there is at least one specified connection point Cs.

A state in which the photovoltaic elements PV located in the respective stages of series circuits are arranged in multiple completely different arrangements can be easily realized by connecting multiple photovoltaic modules 1 to each other, thus making it possible to realize a state in which the photovoltaic elements PV are distributed uniformly, and the influence of a shadow on respective stages is made uniform. This makes it possible to improve the power generation efficiency.

### Second Embodiment

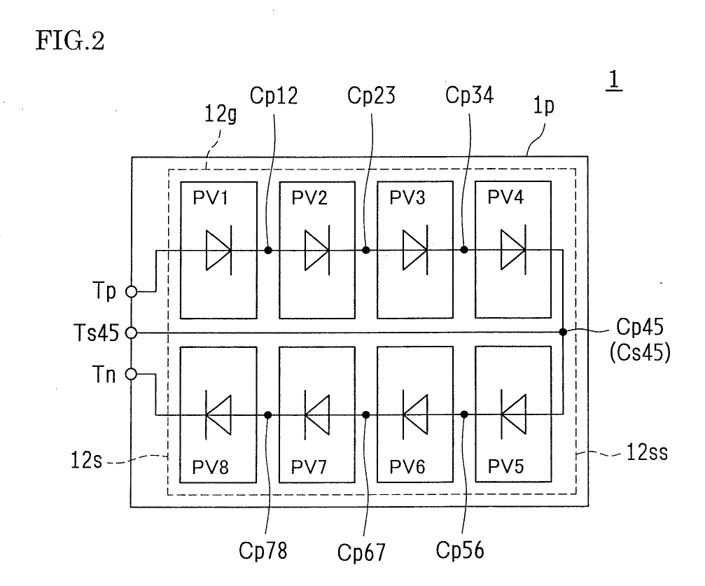

The following describes a photovoltaic module 1 according to a second embodiment with reference to FIG. 2. Since the basic configuration is similar to that of the photovoltaic module 1 of the first embodiment, the same reference signs will be used when appropriate, and the following will mainly describe the differences.

FIG. 2 is a conceptual diagram that conceptually shows the photovoltaic elements PV1 to PV8 in the photovoltaic module 1 and the arrangement and connections of a cluster power generation unit 12g according to the second embodiment of the present invention.

In the photovoltaic module 1 of the present embodiment, an eight-element series circuit is configured by the photovoltaic elements PV1 to PV8 that are sectioned into two sections with the series number k=4. Accordingly, the photovoltaic module 1 includes the specified terminal Ts45 that is connected to the output terminal Tp, the output terminal Tn, and the specified connection point Cs45 (the connection point Cp45 between the photovoltaic element PV4 and the photovoltaic element PV5).

In the cluster power generation unit 12g, the photovoltaic elements PV are arranged in two rows and four columns. The photovoltaic elements PV1 to PV4 are arranged in the first row from the top, and the photovoltaic elements PV5 to PV8 are arranged in the second row from the top. Also, the photovoltaic element PV1 and the photovoltaic element PV8 are arranged in the first column from the left, the photovoltaic element PV2 and the photovoltaic element PV7 are arranged in the second column from the left, the photovoltaic element PV3 and the photovoltaic element PV6 are arranged in the third column from the left, and the photovoltaic element PV4 and the photovoltaic element PV5 are arranged in the fourth column from the left. Moreover, the photovoltaic elements PV are sectioned into sections of four each and arranged so as to form a new line in the opposite direction after each section.

The present embodiment describes conditions for eliminating the need for a bypass diode (not shown) in the case where the series number k of the photovoltaic elements PV in the sections is raised.

Let Voc be the open voltage and Vp be the peak inverse voltage for each of the photovoltaic elements PV (photovoltaic elements PV1 to PV8), and consider a series circuit in which the photovoltaic elements PV are sectioned into sections having the same series number k (series number k=4 in the present embodiment). (Note that in the present embodiment, there are two sections, namely a series circuit including the photovoltaic elements PV1 to PV4 and a series circuit including the photovoltaic elements PV5 to PV8.)

Assuming the case where in either of the series circuits (either the series circuit including the photovoltaic elements PV1 to PV4 or the series circuit including the photovoltaic elements PV5 to PV8), the one photovoltaic element PV1 does not operate (generate electricity) due to not being irradiated with irradiation light because of a shadow (the case of a shadow according to which the photovoltaic element PV1, for example, does not generate electricity in the series circuit including the photovoltaic elements PV1 to PV4), the maximum output voltage of the operating (electricity-generating) photovoltaic elements PV (photovoltaic elements PV2 to PV4) is (k−1)×Voc.

Specifically, if the peak inverse voltage Vp is greater than (k−1)×Voc, assuming that a short-circuit occurs at the two ends of the photovoltaic elements PV1 to PV4 (the anode terminal of photovoltaic element PV1 and the cathode terminal of the photovoltaic element PV4), which make up one of the series circuits, and that the potential difference between the two ends is 0, the reverse voltage applied to the photovoltaic element PV1 that is not operating (generating electricity) is (k−1)×Voc. In other words, since only a voltage that is lower than the peak inverse voltage Vp is applied, the photovoltaic element PV1 (photovoltaic element PV) does not cause withstand voltage breakdown.

On the other hand, if the peak inverse voltage Vp is less than or equal to (k−1)×Voc, the generated voltage (output voltage=(k−1)×Voc) of the operating (electricity-generating) photovoltaic elements PV (photovoltaic elements PV2 to PV4) is applied to the photovoltaic element PV1 that is not operating (generating electricity) as a reverse voltage that is greater than or equal to the peak inverse voltage Vp.

At this time, the series circuit including the photovoltaic elements PV1 to PV4 enters a state of continuing to generate electricity with an output voltage that is less than or equal to (k−1)×Voc−Vp. This state is a state in which a current flows to the photovoltaic element PV1 that acts as a resistance load due to not operating (generating electricity), and in the worst case scenario, there is the risk of the photovoltaic element PV1 breaking down due to heat generation (hotspot phenomenon). The hotspot phenomenon occurs more readily as the series number k rises, and becomes more problematic when attempting to output a higher voltage. In other words, in order to prevent the hotspot phenomenon, the open voltage Voc, the peak inverse voltage Vp, and the series number k need to be set so as to satisfy the relationship Vp>(k−1)×Voc.

Specifically, with the photovoltaic module 1 of the present embodiment, letting Voc be the open voltage and Vp be the peak inverse voltage for the photovoltaic elements PV, and letting the series number be k (k≧2), it is preferable that the relationship Vp>(k−1)×Voc is satisfied.

Accordingly, in the photovoltaic module 1 of the present embodiment, the specified connection point Cs (e.g., the specified connection point Cs45) is connected to the specified connection point Cs45 (not shown) corresponding to the same series stage in another photovoltaic module 1 (not shown), and the photovoltaic elements PV are configured so as to satisfy the relationship Vp>(k−1)×Voc, thus enabling preventing the hotspot phenomenon without the connection of a bypass diode, which enables reducing the number of parts so as to improve productivity and reliability.

In other words, with the photovoltaic module 1 of the present embodiment, the condition for the peak inverse voltage of the photovoltaic elements PV is set to Vp>(k−1)×Voc for the series circuits defined by the series number k, thus enabling preventing the hotspot phenomenon and eliminating the need for a bypass diode.

The output terminal Tp, the output terminal Tn, and the specified terminal Ts45 are arranged along one side 12s formed by the cluster power generation unit 12g. This obtains an effect similar to that of the first embodiment. Also, a configuration is possible in which the output terminal Tp, the output terminal Tn, and the specified terminal Ts45 are respectively branched and arranged along two sides (the side 12s and a side 12ss) formed by the cluster power generation unit 12g on opposite sides (see FIG. 7).

Also, a configuration is possible in which the output terminal Tp, the output terminal Tn, and the specified terminal Ts45 are arranged in one corner portion formed by the cluster power generation unit 12g, or are respectively branched and arranged in two or more corner portions (preferably in all four corner portions). For example, a configuration is possible in which the output terminal Tp and the output terminal Tn are arranged on one side (or respectively branched and arranged on multiple sides) formed by the cluster power generation unit 12g, and the specified terminal Ts45 is arranged in one corner portion (or branched and arranged in two or more corner portions) formed by the cluster power generation unit 12g.

Also, a configuration is possible in which, when necessary, any or all of the output terminal Tp, the output terminal Tn, and the specified terminal Ts are provided on the back face of the cluster power generation unit 12g.

Note that FIG. 5B shows a specific arrangement example.

### Third Embodiment

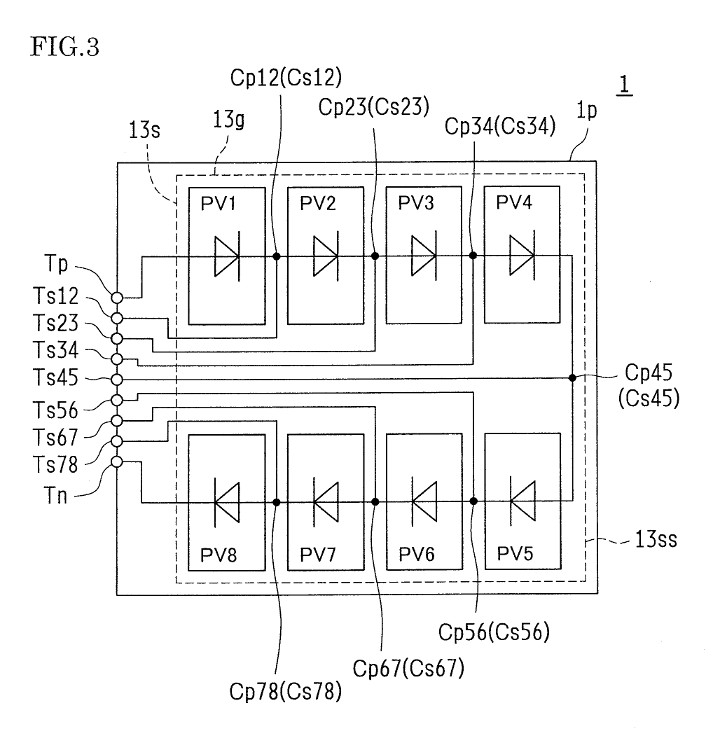

The following describes a photovoltaic module 1 according to a third embodiment with reference to FIG. 3. Since the basic configuration is similar to that of the photovoltaic module 1 of the first and second embodiments, the same reference signs will be used when appropriate, and the following will mainly describe the differences.

FIG. 3 is a conceptual diagram that conceptually shows the photovoltaic elements PV1 to PV8 in the photovoltaic module 1 and the arrangement and connections of a cluster power generation unit 13g according to the third embodiment of the present invention.

The arrangement of the photovoltaic elements PV in the photovoltaic module 1 (cluster power generation unit 13g) of the present embodiment is similar to that of the photovoltaic module 1 of the second embodiment. The connections of the specified connection points Cs are different from those in the photovoltaic module 1 (cluster power generation unit 12g) of the second embodiment.

With the photovoltaic module 1 of the present embodiment, all of the connection points Cp are specified connection points Cs (specified connection points Cs12 to Cs78 corresponding to the connection points Cp12 to Cp78).

Accordingly, with the photovoltaic module 1 of the present embodiment, all of the series-connected photovoltaic elements PV (photovoltaic elements PV1 to PV8) of the cluster power generation unit 13g can be connected in parallel to another photovoltaic module 1 (not shown), thus enabling highly suppressing the influence of a shadow and enabling suppressing a reduction in power generation efficiency.

Specifically, by setting all of the connection points Cp (connection points Cp12 to Cp78) as specified connection points Cs (specified connection points Cs12 to Cs78) in the photovoltaic module 1 of the present embodiment, a parallel circuit is configured with respect to all of the photovoltaic elements PV (photovoltaic elements PV1 to PV8), thus enabling minimizing the influence of shadows on individual photovoltaic elements PV.

Note that the specified connection points Cs12 to Cs78 are respectively connected to specified terminals Ts12 to Ts78.

In addition to the output terminal Tp and the output terminal Tn, the photovoltaic module 1 includes seven specified terminals Ts (a specified terminal Ts12, a specified terminal Ts23, a specified terminal Ts34, a specified terminal Ts45, a specified terminal Ts56, a specified terminal Ts67, and a specified terminal Ts78). Similarly to the output terminal Tp and the output terminal Tn, the specified terminals Ts are arranged along one side 13s formed by the cluster power generation unit 13g. This obtains an effect similar to that of the first embodiment.

A configuration is possible in which the output terminal Tp, the output terminal Tn, and the specified terminals Ts (the specified terminals Ts12 to Ts78) are respectively branched and arranged along two sides (the side 13s and a side 13ss) formed by the cluster power generation unit 13g on opposite sides (see FIG. 7).

In the photovoltaic module 1 of the present embodiment, all of the connection points Cp are connected to the specified terminals Ts as the specified connection points Cs. Accordingly, by connecting multiple photovoltaic modules 1 in parallel, it is possible to minimize the influence of partial shadows having entirely unpredictable shapes. Also, if a photovoltaic system is configured by connecting groups of parallel-connected photovoltaic modules 1 in series, the expected value of electricity generation can be maximized.

Also, providing specified terminals Ts for all of the connection points Cp enables freely selecting (setting) the connection points Cp (specified connection points Cs) that are to be parallel-connected, and enables freely realizing parallel connections according to specifications, arrangement positions, and the like.

### Fourth Embodiment

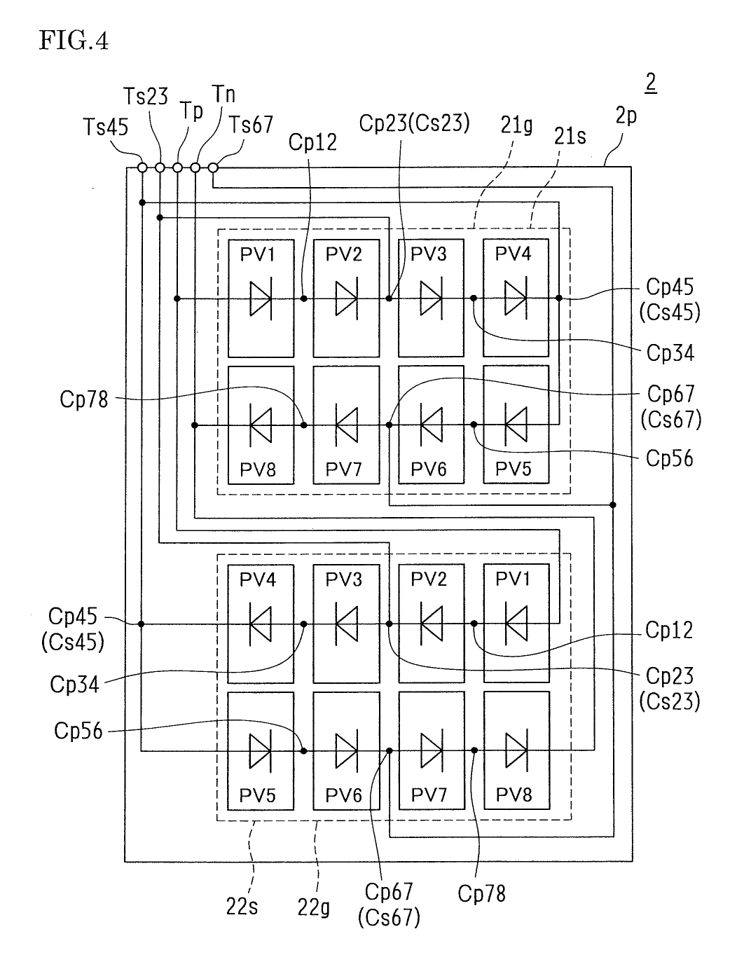

The following describes a photovoltaic module 2 according to a fourth embodiment with reference to FIG. 4. Since the basic configuration of the photovoltaic module 2 is similar to that of the photovoltaic module 1 of the first to third embodiments, the same reference signs will be used when appropriate, and the following will mainly describe the differences.

FIG. 4 is a conceptual diagram that conceptually shows the photovoltaic elements PV1 to PV8 in the photovoltaic module 2 and the arrangement and connections of a cluster power generation unit 21g and a cluster power generation unit 22g according to the fourth embodiment of the present invention.

The photovoltaic module 2 of the present embodiment includes the cluster power generation unit 21g and the cluster power generation unit 22g. In other words, the photovoltaic module 2 includes multiple cluster power generation units. The cluster power generation unit 21g and the cluster power generation unit 22g are both eight-element series (photovoltaic elements PV1 to PV8) series circuits (series circuits having the same configuration that can be connected to each other in parallel) that are sectioned into four sections with the series number k=2. The cluster power generation unit 21g and the cluster power generation unit 22g are connected to each other in parallel, and furthermore are arranged so as to be parallel in the column direction (vertical direction in FIG. 4). Specifically, in FIG. 4, the upper stage is the cluster power generation unit 21g, and the lower stage is the cluster power generation unit 22g, thus configuring an eight-series×two-parallel circuit. Note that the cluster power generation unit 21g and the cluster power generation unit 22g can be arranged so as to be parallel in the row direction.

Also, the cluster power generation unit 21g and the cluster power generation unit 22g are connected in parallel to the output terminal Tp and the output terminal Tn, and are similarly connected in parallel to the specified terminals Ts (the specified terminal Ts23, the specified terminal Ts45, and the specified terminal Ts67).

The photovoltaic elements PV1 to PV8 are connected to each other at the seven connection points Cp12 to Cp78, and are sectioned into sections with the series number k=2, and therefore three connection points are connected to the specified terminals Ts as specified connection points, namely the specified connection point Cs23 (connection point Cp23), the specified connection point Cs45 (connection point Cp45), and the specified connection point Cs67 (connection point Cp67). Specifically, the specified connection point Cs23 is connected to the specified terminal Ts23, the specified connection point Cs45 is connected to the specified terminal Ts45, and the specified connection point Cs67 is connected to the specified terminal Ts67.

The output terminal Tp, the output terminal Tn, and the specified terminals Ts are shared by the cluster power generation units that are connected to each other in parallel (the cluster power generation unit 21g and the cluster power generation unit 22g).

The output terminal Tp, the output terminal Tn, and the specified terminals Ts (the specified terminal Ts23, the specified terminal Ts45, and the specified terminal Ts67) are arranged so as to be aggregated together at one corner portion (the upper left portion in FIG. 4) formed by the cluster power generation unit 21g. Accordingly, the photovoltaic module 2 can be easily connected to another photovoltaic module 1 that is arranged adjacent thereto, thus making it easier to increase the capacity through a dense arrangement (see FIG. 6).

Multiple cluster power generation units (the two cluster power generation units 21g and 22g) are arranged in the photovoltaic module 2 of the present embodiment. Accordingly, it is possible to configure a distributed-arrangement photovoltaic module 2 in which photovoltaic elements PV that are connected in the same series stage of the cluster power generation units 21g and 22g can be arranged so as to be distributed according to the number of cluster power generation units (the two cluster power generation units 21g and 22g in the present embodiment), thus making it possible to reliably diminish the influence of a shadow. The greater the number of cluster power generation units that are connected in parallel, the more the degree of distribution can be improved.

In the cluster power generation unit 21g, the photovoltaic elements PV1 to PV4 are arranged from left to right in the row direction, and the photovoltaic elements PV5 to PV8 are arranged from right to left in the row direction. Also, the photovoltaic elements PV4 and PV5 are connected from top to bottom in the column direction.

In the cluster power generation unit 22g, the photovoltaic elements PV1 to PV4 are arranged from right to left in the row direction, and the photovoltaic elements PV5 to PV8 are arranged from left to right in the row direction. Also, the photovoltaic elements PV4 and PV5 are connected from top to bottom in the column direction.

Since the photovoltaic module 2 includes the cluster power generation unit 21g and the cluster power generation unit 22g, the photovoltaic elements PV are arranged in four rows and four columns. Specifically, four rows are configured such that the photovoltaic elements PV1 to PV4 of the cluster power generation unit 21g are arranged in the first row from the top, the photovoltaic elements PV5 to PV8 of the cluster power generation unit 21g are arranged in the second row from the top, the photovoltaic elements PV1 to PV4 of the cluster power generation unit 22g are arranged in the third row from the top, and the photovoltaic elements PV5 to PV8 of the cluster power generation unit 22g are arranged in the fourth row from the top.

Also, four columns are configured such that the photovoltaic elements PV1 and PV8 of the cluster power generation unit 21g and the photovoltaic elements PV4 and PV5 of the cluster power generation unit 22g (in order from the first row) are arranged in the first column from the left, the photovoltaic elements PV2 and PV7 of the cluster power generation unit 21g and the photovoltaic elements PV3 and PV6 of the cluster power generation unit 22g (in order from the first row) are arranged in the second column from the left, the photovoltaic elements PV3 and PV6 of the cluster power generation unit 21g and the photovoltaic elements PV2 and PV7 of the cluster power generation unit 22g (in order from the first row) are arranged in the third column from the left, and the photovoltaic elements PV4 and PV5 of the cluster power generation unit 21g and the photovoltaic elements PV1 and PV8 of the cluster power generation unit 22g (in order from the first row) are arranged in the fourth column from the left.

Specifically, a comparison of the arrangements of the photovoltaic elements PV connected in the same series stages shows that, for example, the photovoltaic elements PV1 and PV2 of the cluster power generation unit 21g are arranged in the first and second columns from the left in the first row from the top. In contrast, the photovoltaic elements PV1 and PV2 of the cluster power generation unit 22g are arranged in the fourth and third columns from the left in the third row from the top. In other words, even photovoltaic elements PV that are in the same series stage are arranged so as to be distributed in entirely separate positions.

In other words, with the photovoltaic module 2 of the present embodiment, the photovoltaic elements PV in one of the cluster power generation units (e.g., the cluster power generation unit 21g) and the photovoltaic elements PV in another one of the cluster power generation units (e.g., the cluster power generation unit 22g) are arranged so as to be distributed at mutually different positions with respect to the same series stage.

With the photovoltaic module 2, the arrangement of the photovoltaic elements PV (i.e., the positions where they appear on the surface of the cluster power generation unit) is set so as to be different between multiple cluster power generation units (the cluster power generation unit 21g and the cluster power generation unit 22g), thus making it possible for parallel-connected photovoltaic elements PV to be distributed discretely with respect to each other. This further improves the degree of distribution in the arrangement of photovoltaic elements PV that are connected in parallel in the same series stage, thus enabling further raising the effect of the distributed arrangement.

The following is a specific description of the concept of “the arrangements of photovoltaic elements PV are mutually different with respect to the same series stage” in the case of FIG. 4.

Specifically, this means that in the cluster power generation unit 21g arranged in the upper stage, the photovoltaic element PV1 is arranged at the top left (first row, first column), and the photovoltaic element PV8 is arranged at the bottom left (second row, first column), whereas in the cluster power generation unit 22g arranged in the lower stage, the photovoltaic element PV1 is arranged at the top right (third row, fourth column), and the photovoltaic element PV8 is arranged at the bottom right (fourth row, fourth column). Therefore, the arrangements (positions) of the photovoltaic elements PV are different between the surfaces formed by the cluster power generation units (the cluster power generation unit 21g and the cluster power generation unit 22g), and the positions would not overlap each other even if the arrangements were overlapped.

The photovoltaic module 2 can be, for example, mounted on a mounting member 2p (wiring substrate or the like) so as to configure a single unit configuration. Also, although the wiring for the output terminals Tp and Tn and the wiring between the specified connection points Cs and the specified terminals Ts are shown as being aligned with the photovoltaic elements PV for the sake of convenience in the description, such wiring can be arranged on the back face side of the photovoltaic elements PV, for example. Also, the output terminal Tp, the output terminal Tn, and the specified terminals Ts may be connectors CT (see FIGS. 6 and 7), or may be patterned into a wiring substrate or the like.

Also, the output terminal Tp, the output terminal Tn, and the specified terminals Ts do not need to be fixed to the mounting member 2p, and need only be capable of connecting to the outside (e.g., to another photovoltaic module 2 arranged adjacent thereto).

Also, a configuration is possible in which the output terminal Tp, the output terminal Tn, and the specified terminals Ts (the specified terminals Ts23, Ts45, and Ts67) are respectively branched and arranged along two sides (a side 21s and a side 22ss) formed by the cluster power generation unit 21g and the cluster power generation unit 22g on opposite sides (see FIG. 7).

### Fifth Embodiment

The following describes a photovoltaic module 2 according to a fifth embodiment with reference to FIGS. 5A and 5B. Since the basic configuration is similar to that of the photovoltaic modules 1 and 2 of the first to fourth embodiments, the same reference signs will be used when appropriate, and the following will mainly describe the differences.

FIG. 5A is a conceptual diagram that conceptually shows the photovoltaic elements PV1 to PV8 in the photovoltaic module 2 and the arrangement and connections of a cluster power generation unit 23g and a cluster power generation unit 24g according to the fifth embodiment of the present invention.

The photovoltaic module 2 of the present embodiment includes the cluster power generation unit 23g and the cluster power generation unit 24g. In other words, the photovoltaic module 2 includes multiple cluster power generation units. The cluster power generation unit 23g and the cluster power generation unit 24g are both eight-element series (photovoltaic elements PV1 to PV8) series circuits (series circuits having the same configuration that can be connected to each other in parallel) that are sectioned into four sections with the series number k=2.

Specifically, the cluster power generation unit 23g and the cluster power generation unit 24g are arranged so as to be parallel in the row direction (the horizontal direction in FIGS. 5A and 5B), two-series arms form two-parallel arms with each other, and four of the two-series×two-parallel circuits are connected in a series connection configuration. In FIGS. 5A and 5B, the left side is the cluster power generation unit 23g, and the right side is the cluster power generation unit 24g, thus forming an eight-series×two-parallel (an eight-series arm is sectioned into four sections of two each) circuit.

Note that the arrangement of the photovoltaic elements PV (the photovoltaic elements PV1 to PV8) and the specified connection points Cs (the specified connection points Cs23, Cs45, and Cs67) in the cluster power generation unit 23g is the same as the arrangement of the photovoltaic elements PV and the specified connection points Cs in the cluster power generation unit 21g (FIG. 4), and the arrangement of the photovoltaic elements PV (the photovoltaic elements PV1 to PV8) and the specified connection points Cs (the specified connection points Cs23, Cs45, and Cs67) in the cluster power generation unit 24g is the same as the arrangement of the photovoltaic elements PV and the specified connection points Cs in the cluster power generation unit 22g (FIG. 4). Also, the wiring structure (wiring portions WP) of the photovoltaic module 2 of the present embodiment is different from that of the photovoltaic module 2 of the fourth embodiment (FIG. 4).

The photovoltaic module 2 of the present embodiment includes wiring portions WP that are arranged so as to extend in the parallel-arrangement direction DP of the cluster power generation units (the cluster power generation units 23g and 24g), and the output terminals Tp, the output terminals Tn, and the specified terminals Ts are arranged in the wiring portions WP. Accordingly, the photovoltaic modules 2 can be arranged densely using the wiring portions WP, thus facilitating an increase in capacity.

Also, the wiring portions WP include an output wiring portion WPp that is connected to the output terminals Tp and the output terminals Tn and specified wiring portions WPs that are connected to the specified terminals Ts (the specified terminals Ts23, Ts45, and Ts67). The output wiring portion WPp is arranged in a central region RWc with respect to an intersecting direction DR that intersects with the parallel-arrangement direction DP, and the specified wiring portions WPs are symmetrically arranged in side regions RWs at the two ends in the intersecting direction DR.

Accordingly, when another photovoltaic module 2 (not shown) that is arranged adjacent to the above-described photovoltaic module 2 is rotated 180 degrees, the specified terminals Ts thereof can be easily connected together in parallel, and it is also easy to raise the degree of distribution of the photovoltaic elements PV in a dense arrangement.

The mounting member 2p is configured by a wiring substrate, for example. The wiring substrate that configures the mounting member 2p has a long rectangular shape that extends in the parallel-arrangement direction in accordance with the arrangement of the cluster power generation unit 23g and the cluster power generation unit 24g, and includes the wiring portions WP that extend in the lengthwise direction (parallel-arrangement direction DP). Note that although the wiring portions WP are described as being on the same face as the cluster power generation units 23g and 24g for the sake of convenience in the description, they may be arranged on the back face side of the mounting member 2p (wiring substrate) on which the cluster power generation unit 23g and the cluster power generation unit 24g are arranged, for example. Arranging the wiring portions WP (the central region RWc and the side regions RWs) on the back face side of the mounting member 2p enables improving the percentage of area occupied by the light receiving faces of the photovoltaic elements PV.

Current from the photovoltaic elements PV flows as is to the output wiring portion WPp, and a slight amount of current flows to the specified wiring portions WPs in order to eliminate the potential difference between the specified terminals Ts. Accordingly, it is preferable that the output wiring portion WPp is wiring whose current capacity is different from that of the specified wiring portions WPs. Specifically, the output wiring portion WPp is wiring whose current capacity is high, and the specified wiring portions WPs are wiring whose current capacity is low.

The output terminals Tp and the output terminals Tn are arranged along one side 23s formed by the cluster power generation unit 23g and along one side 24s formed by the cluster power generation unit 24g. In other words, a pair of a output terminal Tp and a output terminal Tn is arranged on both sides in the parallel-arrangement direction DP.

The output wiring portion WPp is arranged in the central region RWc (wiring region) that connects the output terminals Tp and the output terminals Tn arranged on both sides in the parallel-arrangement direction DP, and is connected to both of the output terminals Tp and both of the output terminals Tn.

The specified wiring portions WPs are symmetrically arranged in the side regions RWs that arranged on both sides of the mounting member 2p with respect to the intersecting direction DR. Specifically, a specified terminal Ts23, a specified terminal Ts45, a specified terminal Ts67, (the output wiring portion WPp: central region RWc), a specified terminal Ts67, a specified terminal Ts45, and a specified terminal Ts23 are arranged in the stated order from the outer side on one side in the intersecting direction DR to the outer side on the other side in the intersecting direction DR.

The wiring portions WP may be formed so as to be integrated with the member on which the cluster power generation units 23g and 24g are arranged (mounting member 2p), or may be formed as a separate member. Also, in the case where the wiring portions WP are configured by a stacked wiring substrate, the current capacity can be increased by arranging the output wiring portion WPp in a different layer from the specified wiring portions WPs, thus enabling suppressing a voltage drop and power consumption due to the wiring portions WP.

In the present embodiment, the output terminals Tp, the output terminals Tn, and the specified terminals Ts are respectively branched and arranged along two sides (the side 23s and the side 24s) formed by the cluster power generation units 23g and 24g on opposite sides. According to this configuration, photovoltaic modules 2 can easily be two-dimensionally connected to other photovoltaic modules 2 that are arranged adjacent thereto, thus making it even easier to increase the capacity through a dense arrangement.

The output terminals Tp, the output terminals Tn, and the specified terminals Ts may take any form as long they enable connection with another photovoltaic module 2. For example, it is possible to apply connection pads formed on the mounting member 2p (wiring substrate) or connectors CT connected to the mounting member 2p (see FIGS. 6 and 7).

Note that cases where the photovoltaic module 1 includes eight photovoltaic elements PV and the photovoltaic module 2 includes 8×2=16 photovoltaic elements PV are described in the first to fifth embodiments, these are simply exemplary cases for the purpose of illustration, and it is possible to further improve the degree of distribution and the capacity by configuring a photovoltaic module 1 or a photovoltaic module 2 that includes an even greater number of photovoltaic elements PV.

FIG. 5B is a conceptual diagram that conceptually shows a variation of the arrangement of the specified terminals Ts (the specified terminal Ts23, Ts45, and Ts67) of the wiring in the photovoltaic module 2 shown in FIG. 5A.

In FIG. 5A, the specified terminals Ts (the specified terminals Ts23, Ts45, and Ts67) are symmetrically arranged on two opposing sides. In contrast, in the variation of FIG. 5B, the specified terminals Ts (the specified terminals Ts23, Ts45, and Ts67) are arranged so as to be aggregated together in corner portions formed by the cluster power generation units 23g and 24g (corner portions formed by the mounting member 2p). Note that although this figure shows the case where the specified terminals Ts are aggregated together, the output terminals (output terminals Tp and Tn) may be aggregated together, or both the specified terminals Ts and the output terminals may be aggregated together.

Although this figure shows the case where the specified terminals Ts are aggregated together in four corner portions, the specified terminals Ts need only be arranged in at least a pair of corner portions (two corner portions) with respect to the horizontal direction in the case of development in the row direction. Also, the specified terminals Ts need only be arranged in at least a pair of corner portions (two corner portions) in the vertical direction in the case of development in the column direction. Also, if the specified terminals Ts are arranged in the four corner portions, development is possible in not only the row and column directions, but also in the diagonal directions. In other words, it is preferable that the specified terminals Ts or the output terminals (the output terminals Tp and Tn) are arranged in at least two or more corner portions.

Note that although the shape of the terminals in the corner portions is schematically shown as being a shape that diagonally intersects the sides of the mounting member 2p, it is possible to improve connectivity with an opposing substrate by forming tabs, for example. Also, applying the corner portions eliminates interference in terms of area with an opposing wiring substrate, thus making it possible to further improve the density of the arrangement.

### Sixth Embodiment

The following describes a photovoltaic module array 5 according to a sixth embodiment with reference to FIG. 6. The photovoltaic module array 5 of the present embodiment can generate a higher amount of electricity since photovoltaic modules 1 or photovoltaic modules 2 of the first to fifth embodiments are arranged in lines in a planar manner. Since the basic configuration is similar to that of the photovoltaic modules 1 and 2 of the first to fifth embodiments, the same reference signs will be used when appropriate, and the following will mainly describe the differences.

FIG. 6 is a conceptual diagram that conceptually shows the arrangement and connections of photovoltaic modules 1 in the photovoltaic module array 5 according to the sixth embodiment of the present invention.

The photovoltaic module array 5 of the present embodiment includes an arrangement of multiple photovoltaic modules 1 (see the first to third embodiments) or photovoltaic modules 2 (see the fourth and fifth embodiments) instead of the photovoltaic modules 1. Connections to the photovoltaic modules 1 (or the photovoltaic modules 2) are made via linking wiring CWP.

Although FIG. 6 illustrates an example where the photovoltaic modules 1 are arranged in a matrix (a total of six in three rows and two columns), the use of the linking wiring CWP enables freely setting the arrangement (positions) of the photovoltaic modules 1 or photovoltaic modules 2. This enables arranging the photovoltaic elements PV in an even further distributed manner.

For example, the arrangement of the photovoltaic modules 1 can be freely set to an arrangement other than a matrix, and an arrangement (positions) that is optimum for the installation location can be selected by using an arrangement that has increased irregularity.

Power collected by the linking wiring CWP is converted into required power by a power conversion apparatus 10. Note that a photovoltaic system is configured by the combination of the photovoltaic module array 5 and the power conversion apparatus 10.

The photovoltaic module array 5 of the present embodiment includes multiple photovoltaic modules 1 (or photovoltaic modules 2) and the linking wiring CWP that links the photovoltaic modules 1 (or photovoltaic modules 2) to each other. Also, the photovoltaic modules 1 are photovoltaic modules according to any of the first to third embodiments, and the photovoltaic modules 2 are photovoltaic modules according to the fourth embodiment.

Accordingly, the photovoltaic module array 5 enables easily and reliably suppressing the influence of a shadow on the photovoltaic elements PV so as to improve the power generation efficiency, and enables stably generating a large amount of electricity from light.

Note that it is preferable that the wiring connected to the output terminals Tp and the output terminals Tn has a lower resistance and a higher current capacity than the wiring connected to the specified terminals Ts.

Providing the photovoltaic modules 1 and the linking wiring CWP with connectors CT enables improving work efficiency by making the linking operation (connection operation) easier. For the sake of convenience in the description, the linking wiring CWP and the connectors CT are shown as being arranged in parallel with the photovoltaic modules 1. However, it is preferable that the linking wiring CWP and the connectors CT are arranged on the back face side when the photovoltaic modules 1 are arranged densely.

The photovoltaic module array 5 may be configured such that the photovoltaic elements PV included in the photovoltaic modules 1 (photovoltaic modules 2) are arranged densely on a common arrangement member (mounting member). One example of a common arrangement member is a glass substrate that forms a common light receiving face.

Also, although the example in which the photovoltaic modules 1 (or the photovoltaic modules 2) are in a connection arrangement of two each in the row direction and three each in the column direction (a three-row×two-column arrangement) is shown, an even higher capacity photovoltaic module array (photovoltaic system) can be configured by linking an even greater number of photovoltaic modules.

### Seventh Embodiment

The following describes a photovoltaic module array 5 according to a seventh embodiment with reference to FIG. 7. Since the basic configuration of the photovoltaic module array 5 of the present embodiment is similar to that of the photovoltaic module array 5 of the sixth embodiment, the same reference signs will be used when appropriate, and the following will mainly describe the differences.

FIG. 7 is a conceptual diagram that conceptually shows the arrangement and connections of photovoltaic modules 1c in the photovoltaic module array 5 according to the seventh embodiment of the present invention.

The photovoltaic module array 5 of the present embodiment includes an arrangement of multiple photovoltaic modules 1c (variations of the photovoltaic module 1). Connections to the photovoltaic modules 1c are made via the linking wiring CWP.

Although FIG. 7 shows the example where the photovoltaic modules 1c are arranged in a matrix (a total of nine in three rows and three columns), the use of the linking wiring CWP enables freely setting the arrangement of the photovoltaic modules 1c to an arrangement other than a matrix. This enables arranging the photovoltaic elements PV in an even further distributed manner.

Power collected by the linking wiring CWP is converted into required power by the power conversion apparatus 10. Note that a photovoltaic system is configured by the combination of the photovoltaic module array 5 and the power conversion apparatus 10.

The photovoltaic modules 1c each include the output terminals Tp, the output terminals Tn, and the specified terminals Ts of the photovoltaic module 1 in both directions. Specifically, in each of the photovoltaic modules 1c, the output terminals Tp, the output terminals Tn, and the specified terminals Ts are respectively branched and arranged along two sides (the side 11s and the side 11ss shown in FIG. 1) formed by the cluster power generation unit 11g on opposite sides.

The photovoltaic module array 5 of the present embodiment includes multiple photovoltaic modules 1c and the linking wiring CWP that links the photovoltaic modules 1c to each other. Also, the photovoltaic modules 1c are variations of the photovoltaic module 1 (photovoltaic module 2) according to any of the first to fourth embodiments (the output terminals Tp, the output terminals Tn, and the specified terminals Ts are arranged in both directions). Note that although the example of the photovoltaic modules 1c is shown, the photovoltaic modules 2 of the fifth embodiment (FIGS. 5A and 5B) may be applied.

Accordingly, the photovoltaic module array 5 enables easily and reliably suppressing the influence of a shadow on the photovoltaic elements PV so as to improve the power generation efficiency, and enables stably generating a large amount of electricity from light.

Note that providing the photovoltaic modules 1c with connectors CT on both sides enables improving work efficiency by making the linking operation (connection operation) easier. This also facilitates connections on both sides when arranged in a planar manner.

Note that the first to seventh embodiments can be applied to each other to the extent that contradictions do not arise.

The present invention can be embodied in various other forms without departing from the spirit or main features of the invention. The above-described embodiments are therefore merely exemplary in all respects, and are not intended to be interpreted in a limiting manner. The scope of the present invention is indicated by the scope of the claims, and is not intended to be restricted to this specification in any way. Furthermore, all variations and modifications within the scope equivalent to the scope of the claims are encompassed in the scope of the present invention.

What is claimed is:

1. A photovoltaic module comprising:
a cluster power generation unit in which a plurality of photovoltaic elements are connected in series via connection points;
a pair of output terminals connected to respective ends of a series circuit formed by the cluster power generation unit; and
a specified terminal connected to a specified connection point that is specified from among the connection points.

2. The photovoltaic module according to claim 1, wherein the specified connection point is a connection point at a boundary between sections obtained by sectioning the photovoltaic elements of the cluster power generation unit into sections of the same series number.

3. The photovoltaic module according to claim 2, wherein letting Voc be an open voltage and Vp be a peak inverse voltage of the photovoltaic elements, and letting the series number be k (k≧2), the relationship Vp>(k−1)×Voc is satisfied.

4. The photovoltaic module according to claim 1,
wherein all of the connection points are specified connection points.

5. The photovoltaic module according to claim 1, wherein a plurality of the cluster power generation units are arranged.

6. The photovoltaic module according to claim 5, wherein an arrangement of the photovoltaic elements in one of the cluster power generation units and an arrangement of the photovoltaic elements in another one of the cluster power generation units are mutually different with respect to the same series stage.

7. The photovoltaic module according to claim 1, wherein the output terminals and/or the specified terminal are arranged along one side formed by the cluster power generation unit, or are arranged so as to be aggregated together in a corner portion formed by the cluster power generation unit.

8. The photovoltaic module according to claim 1, wherein the output terminals and/or the specified terminal are respectively branched and arranged along two sides formed by the cluster power generation unit on opposite sides, or are arranged so as to be aggregated together in two or more corner portions formed by the cluster power generation unit.

9. The photovoltaic module according to claim 5, comprising:
a wiring portion arranged so as to extend in a parallel-arrangement direction of the plurality of cluster power generation units,
wherein the output terminals and the specified terminal are arranged in the wiring portion.

10. The photovoltaic module according to claim 9,
wherein the wiring portion comprises output wiring that is connected to the output terminals and specified wiring that is connected to the specified terminal,
the output wiring is arranged in a central region with respect to an intersecting direction that intersects with the parallel-arrangement direction, and
the specified wiring is symmetrically arranged in side regions at two ends in the intersecting direction.

11. A photovoltaic module array comprising a plurality of photovoltaic modules and linking wiring that links the photovoltaic modules to each other,
wherein the photovoltaic modules are each the photovoltaic module according to any one of claims 1 to 10.
